(19) United States
(12) Patent Application Publication
(10) Pub. No.: US 2015/0017785 A1
(43) Pub. Date: Jan. 15, 2015

(54) METHOD OF FORMING SALICIDE BLOCK WITH REDUCED DEFECTS

(71) Applicant: Shanghai Huali Microelectronics Corporation, Shanghai (CN)

(72) Inventors: Meimei Gu, Shanghai (CN); Chien Wei Chen, Shanghai (CN); Yijun Yi, Shanghai (CN); Hsu Sheng Chang, Shanghai (CN)

(73) Assignee: Shanghai Huali Microelectronics Corporation, Shanghai (CN)

(21) Appl. No.: 14/081,771

(22) Filed: Nov. 15, 2013

(30) Foreign Application Priority Data
Jul. 9, 2013 (CN) 201310287393.4

(51) Int. Cl. H01L 21/285; H01L 21/322

(52) U.S. Cl. CPC H01L 21/28518; H01L 21/3221; H01L 21/2855
USPC 438/473

(57) ABSTRACT

A method of forming a salicide block with reduced defects is disclosed, the method including performing an ultraviolet cure process on a silicon nitride layer deposited in a previous step. High-energy ultraviolet light used in the ultraviolet cure process breaks the hydrogen-containing chemical bonds such as silicon-hydrogen and nitrogen-hydrogen in the silicon nitride layer, and the dissociated hydrogen forms molecular hydrogen which is thereafter evacuated away by a vacuuming apparatus. In this way, the hydrogen content in the silicon nitride layer can be effectively decreased and the reaction between hydrogen in the silicon nitride layer and photoresist subsequently coated thereon can hence be reduced. As a result, a salicide block with reduced defects can be obtained, thus improving process reliability and product yield.

### CROSS-REFERENCES TO RELATED APPLICATIONS

This application claims the priority of Chinese patent application number 201310287393.4, filed on Jul. 9, 2013, the entire contents of which are incorporated herein by reference.

### TECHNICAL FIELD

The present invention relates generally to the fabrication of semiconductor devices, and in particular to processes involving salicide blocks (SAB). More particularly, the invention relates to a method of forming a salicide block with reduced defects.

### BACKGROUND

In the semiconductor technology, a salicide block is typically fabricated by performing photolithographic and etching processes on a silicon nitride layer deposited by plasma enhanced chemical vapor deposition (PECVD). The salicide block can block the contact between silicon (Si) and metallic substances (e.g., a nickel-platinum (NiPt) alloy) and prevent the growth of metal silicides in corresponding areas. However, the deposited silicon nitride layer inevitably contains the element hydrogen (in a form of SiNx:H), which can easily escape from the deposited silicon nitride layer in a high vacuum condition and actively react with photoresist, thus forming defects in the photoresist and decreasing the product yield.

More specifically, photoresist is typically composed of a photoacid generator (PAG), a resin, a solvent and an additive. Among these four components of photoresist, the PAG produces hydrogen ions (H+) when exposed to light, which will substitute the protecting groups R of the resin in a subsequent baking process, as shown in the following chemical equations, thereby allowing the photoresist to be dissolved in a developer solution.

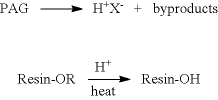

Such chemical equilibriums can be disturbed due to the reaction between the hydrogen that escaped from the deposited silicon nitride layer and the exposed photoresist, thus forming ball defects (one of which is as indicated by the dashed-line circle in FIG. 1) in the photoresist pattern. When this defective photoresist pattern is used to etch the silicon nitride layer to form a salicide block, the abovementioned defects will be transferred into the formed salicide block and finally affect the quality of metal silicides subsequently formed using the defective salicide block.

### SUMMARY OF THE INVENTION

It is therefore an objective of the present invention to overcome the above disadvantages of the prior art by providing a salicide block forming method capable of reducing ball defects in the photoresist pattern.

The foregoing objective is attained by a method of forming a salicide block with reduced defects. The method includes the following steps in the sequence set forth: depositing a silicon nitride layer over a silicon wafer by plasma enhanced chemical vapor deposition, wherein the silicon nitride layer includes hydrogen-containing chemical bonds such as silicon-hydrogen and nitrogen-hydrogen; performing an ultraviolet cure process on the silicon nitride layer to break the hydrogen-containing chemical bonds and removing hydrogen; and patterning the silicon nitride layer by photolithography and etching to form a salicide block.

Preferably, the method may further include the steps of: sputtering a metal over the silicon wafer; performing a rapid annealing process to form metal silicides over portions of the silicon wafer not covered by the salicide block; and stripping away the remaining metal not formed into the metal silicides.

Preferably, performing an ultraviolet cure process on the silicon nitride layer may include: disposing the silicon wafer with the silicon nitride layer deposited thereon in an ultraviolet chamber; and irradiating ultraviolet light on the silicon nitride layer and vacuuming the ultraviolet chamber.

Preferably, hydrogen is removed during vacuuming the ultraviolet chamber.

Preferably, the ultraviolet cure process may be performed at a temperature of 350° C. to 400° C. for 250 seconds to 350 seconds.

Preferably, the ultraviolet cure process may be performed at a temperature of 385° C. for 300 seconds.

Advantageously, after high-energy ultraviolet (UV) light breaks the hydrogen-containing chemical bonds such as silicon-hydrogen (Si—H) and nitrogen-hydrogen (N—H) and generated molecular hydrogen (H₂) is evacuated away by vacuuming the UV chamber, the hydrogen content in the silicon nitride layer can be effectively decreased and the reaction between hydrogen from the silicon nitride layer and photoresist subsequently coated thereon can hence be reduced. As such, a salicide block with reduced defects can be obtained, thus improving process reliability and product yield.

### BRIEF DESCRIPTION OF THE DRAWINGS

A more complete appreciation of the invention and the attendant advantages and features thereof will be readily obtained as the same becomes better understood by reference to the following detailed description when considered in connection with the accompanying drawings, wherein:

FIG. 1 depicts a ball defect formed in an exposed and developed photoresist pattern in accordance with the prior art;

FIG. 2 depicts a flowchart graphically illustrating a method of forming a salicide block in accordance with embodiments of the present invention.

FIG. 3 depicts an embodiment of a UV chamber used in the method of forming a salicide block in accordance with embodiments of the present invention.

FIG. 4 schematically illustrates what happens in a UV cure process employed in the method of forming a salicide block in accordance with embodiments of the present invention.

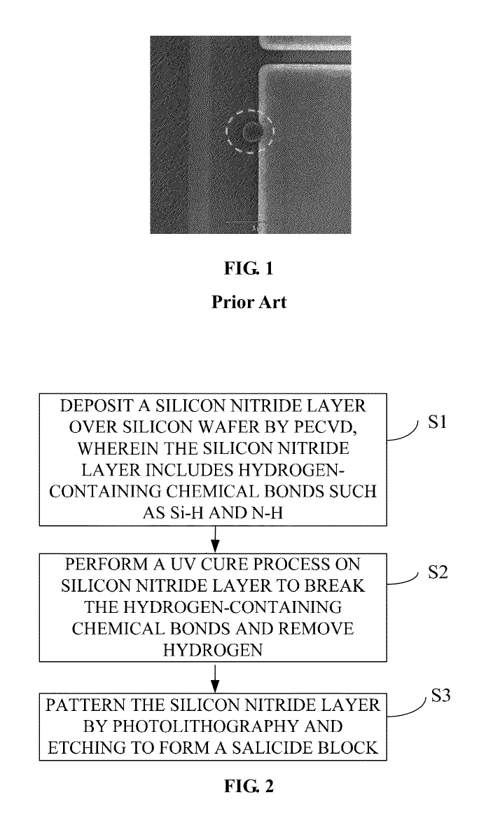

Note that the figures of the accompanying drawings are illustrative only and are not intended to limit the scope of the present invention, and they may not be drawn precisely to scale. Same or analogous reference numbers in the various drawings indicate like elements.

### DETAILED DESCRIPTION OF EXEMPLARY EMBODIMENTS

The present invention will become more apparent and fully understood from the following detailed description of exemplary embodiments thereof, which is to be read in connection with the accompanying drawings.

FIG. 2 is a flow chart graphically illustrating a method of forming a salicide block (SAB) in accordance with the present invention.

As illustrated the method includes the following steps S1 to S3.

In a first step S1, a silicon nitride layer is deposited by, for example, generally plasma enhanced chemical vapor deposition (PECVD). As described in the Background of this disclosure, the deposited silicon nitride layer inevitably contains the element hydrogen (in a form of SiNₓ:H).

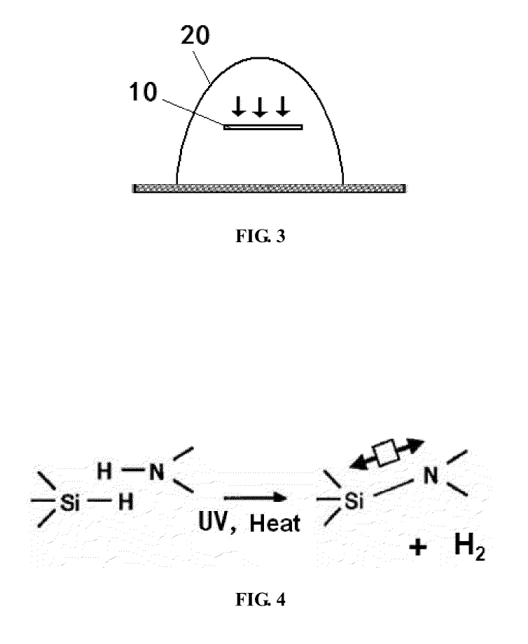

In a second step S2 of the method, an ultraviolet (UV) cure process is performed on the deposited silicon nitride layer. In one specific embodiment, with reference to FIG. 3, the UV cure process can include the following steps: disposing the silicon wafer 10 having the silicon nitride layer deposited thereon in a UV chamber 20; and irradiating UV light (represented by the arrows in FIG. 3) on the silicon nitride layer, and concurrently, exhausting the UV chamber 20 to a certain vacuum degree with a vacuum pump (not shown in FIG. 3).

FIG. 4 schematically illustrates what happens in the UV cure process. Specifically, the high-energy UV light breaks silicon-hydrogen (Si—H), nitrogen-hydrogen (N—H) and other hydrogen-containing chemical bonds in the silicon nitride layer and results in the formation of silicon-nitrogen (Si—N) bonds therein and molecular hydrogen (H₂) which is thereafter evacuated out of the UV chamber by the vacuum pump. As such, the hydrogen content in the silicon nitride layer is advantageously decreased, thus greatly reducing the ball defect-causing reaction between hydrogen from the silicon nitride layer and a certain ingredient of photoresist subsequently coated thereon.

In this step, in order to effectively reduce the hydrogen content in the silicon nitride layer while not causing an over-treatment of the silicon nitride layer, the UV cure process may be preferably performed at a temperature of 350° C. to 400° C. for 250 seconds to 350 seconds.

More preferably, the UV cure process may be performed at a temperature of 385° C. for 300 seconds, so as to most effectively reduce the hydrogen content in the silicon nitride layer.

In a third step S3 of the method, as shown in FIG. 2, photolithographic and etching processes are performed on the silicon nitride layer to form a pattern therein, namely to form the salicide block.

After that, the method may further include the steps of: sputtering a metal (e.g., a nickel-platinum (NiPt) alloy) over the silicon wafer; performing a rapid annealing process to form metal silicides over portions of the silicon wafer that are not covered by the patterned silicon nitride layer (i.e., the salicide block); and stripping away the remaining metal that is not formed into the metal silicides.

From the above description, it can be understood that the method of this invention has the following advantage: it employs a UV cure process using high-energy UV light which can break the Si—H, N—H and other hydrogen-containing chemical bonds in the silicon nitride layer and hence enable the removal of unstable hydrogen, as such, the reaction between hydrogen from the silicon nitride layer and photoresist subsequently coated thereon can hence be reduced, thereby reducing defects and improving process reliability and product yield.

In the existing semiconductor fabrication technology, although the UV cure process has been used in some applications, most of them are focused on the stress memorization technique (SMT) and ultra low-k materials (e.g., Black Diamond™ II (BDII)). In its application in SMT, the UV cure process is used to reduce the hydrogen content of a deposited high hydrogen content silicon nitride layer with the high-energy UV light and thereby enable the silicon nitride layer to gain a high tension stress (refer to “Claude Ortolland, Yasutoshi Okuno, Peter Verheyen, ChristophKerner, Chris Stapelmann, Member, IEEE, Marc Aoulaiche, Naoto Horiguchi, and Thomas Hoffmann, Stress Memorization Technique—Fundamental Understanding and Low-Cost Integration for Advanced CMOS Technology Using a Nonselective Process, IEEE Transactions on Electron Devices, Vol. 56, No. 8, August 2009” for a detailed description of the UV cure process's application in the SMT). Similarly, its application in ultra-low-k materials is also intended for a high tension stress.

It is to be appreciated that, distinct from its above described applications in the SMT and ultra low-k materials, the UV cure process employed in the method of this invention, after the silicon nitride layer has been deposited, is intended to “reduce the reaction between photoresist and hydrogen in the silicon nitride layer”, by breaking the Si—H, N—H and other hydrogen-containing chemical bonds in the layer with the high-energy UV light so as to enable decreasing the hydrogen content in the silicon nitride layer, thereby reducing, or even eliminating, possible defects in the subsequently formed salicide block and hence improving process reliability and product yield.

It should be noted that, as used herein, unless otherwise specified or noted, the terms such as “first”, “second” and “third” are terms to distinguish different components, elements, steps, etc. described in the disclosure, not terms to describe logical or ordinal relationships among the individual components, elements, steps, etc.

It is to be understood that while preferred embodiments have been presented in the foregoing description of the invention, they are not intended to limit the invention in any way. Those skilled in the art can make various alternatives, modifications and equivalent variations to the preferred embodiments in light of the above teachings without departing from the scope of the invention. Thus, it is intended that the present invention covers all such simple modifications, equivalent alternatives and variations.

What is claimed is:

1. A method of forming a salicide block, comprising the following steps in the sequence set forth:
depositing a silicon nitride layer over a silicon wafer by plasma enhanced chemical vapor deposition, wherein the silicon nitride layer includes hydrogen-containing chemical bonds such as silicon-hydrogen and nitrogen-hydrogen;
performing an ultraviolet cure process on the silicon nitride layer to break the hydrogen-containing chemical bonds and removing hydrogen; and
patterning the silicon nitride layer by photolithography and etching to form a salicide block.

2. The method of claim 1, further comprising the steps of:
sputtering a metal over the silicon wafer;
performing a rapid annealing process to form metal silicides over portions of the silicon wafer not covered by the salicide block; and
stripping away the remaining metal not formed into the metal silicides.

3. The method of claim 1, wherein performing an ultraviolet cure process on the silicon nitride layer comprises:
disposing the silicon wafer with the silicon nitride layer deposited thereon in an ultraviolet chamber; and
irradiating ultraviolet light on the silicon nitride layer and vacuuming the ultraviolet chamber.

4. The method of claim 3, wherein hydrogen is removed during vacuuming the ultraviolet chamber.

5. The method of claim 1, wherein the ultraviolet cure process is performed at a temperature of 350° C. to 400° C. for 250 seconds to 350 seconds.

6. The method of claim 5, wherein the ultraviolet cure process is performed at a temperature of 385° C. for 300 seconds.
